(19) United States
(12) Patent Application Publication
(10) Pub. No.: US 2025/0373145 A1
(43) Pub. Date: Dec. 4, 2025

(54) CIRCUITS AND METHODS FOR ONE WIRE COMMUNICATION PROTOCOL

(71) Applicant: Navitas Semiconductor Limited, Dublin (IE)

(72) Inventors: Zhengdong ZHANG, Shanghai (CN); Songming ZHOU, Shanghai (CN)

(73) Assignee: Navitas Semiconductor Limited, Dublin (IE)

(21) Appl. No.: 19/211,001

(22) Filed: May 16, 2025

(30) Foreign Application Priority Data
Jun. 3, 2024 (CN) 202410710794.4

(51) Int. Cl. H02M 1/12; H02M 1/00

(52) U.S. Cl. CPC H02M 1/12; H02M 1/0009

(57) ABSTRACT

A one wire communication protocol for a power supply system is disclosed. In one aspect, a power supply system includes a controller circuit including an output pin, the controller circuit being arranged to transmit a pulse signal having a pulse width at the output pin, a phase circuit including an input pin, a bus connecting the output pin to the input pin, where the phase circuit is arranged to compare the pulse width of the pulse signal to a predetermined threshold and generate a corresponding data signal based on the comparison.

### CROSS REFERENCE TO RELATED APPLICATIONS

This application claims priority to China provisional patent application no. 202410710794.4, for “Circuits and Methods for One Wire Protocol” filed on Jun. 3, 2024, which is hereby incorporated by reference in entirety for all purposes.

### FIELD

The described embodiments relate generally to power converters, and more particularly, the present embodiments relate to circuits and methods for one wire communication protocol used in electronic circuits.

### BACKGROUND

Electronic devices such as computers, servers and televisions, among others, employ one or more electrical power conversion circuits to convert one form of electrical energy to another. Some electrical power conversion circuits convert a high (or low) DC voltage to a lower (or higher) DC voltage using a circuit topology called DC-DC converter. As many electronic devices are sensitive to size and efficiency of the power conversion circuit, new power converters can provide relatively higher efficiency and lower size for the new electronic devices. Current approaches for communication between circuits may use at least two external pins. One pin can be used as an input clock (SCL), and the other as input data (SDA). With the increasing integration of power integrated circuits (IC) and decreasing number of external pins, there is a need in the art for improved communication protocols.

### SUMMARY

In some embodiments, a power supply system is disclosed. The power supply system includes a controller circuit including an output pin, the controller circuit arranged to transmit a pulse signal having a pulse width at the output pin; a phase circuit including an input pin; a bus connecting the output pin to the input pin, where the phase circuit is arranged to compare the pulse width of the pulse signal to a predetermined threshold and generate a corresponding data signal based on the comparison.

In some embodiments, the phase circuit includes a pulse width comparator arranged to compare the pulse width of the pulse signal to the predetermined threshold.

In some embodiments, the phase circuit includes a pulse width comparator that is connected to a pulse generator and to a sampling unit.

In some embodiments, the phase circuit is further arranged to generate a clock signal.

In some embodiments, the clock signal is generated based on a falling edge of the pulse signal.

In some embodiments, the clock signal is generated based on a rising edge of the pulse signal.

In some embodiments, the phase circuit is arranged to generate the corresponding data signal when the pulse width of the pulse signal is greater than the predetermined threshold, and generate a corresponding inverse data signal when the pulse width of the pulse signal is less than the predetermined threshold.

In some embodiments, a communication system is disclosed. The communication system includes a bus; an electronic device having a communication pin connected to the bus, the electronic device arranged to receive a pulse signal having a pulse width via the communication pin, where the electronic device is arranged to compare the pulse width of the pulse signal to a predetermined threshold and generate a corresponding data signal based on the comparison.

In some embodiments, the electronic device is a first electronic device and the communication pin is a first communication pin, and wherein the communication system further comprises a second electronic device having a second communication pin connected to the bus, wherein second electronic device is arranged to transmit the pulse signal.

In some embodiments, the electronic device is arranged to compare the pulse width using a pulse width comparator.

In some embodiments, the electronic device comprises a pulse width comparator, a pulse generator, and a sampling unit.

In some embodiments, the electronic device comprises a pulse generator arranged to generate a clock signal based on a falling edge of the pulse signal.

In some embodiments, a power supply system is disclosed. The power supply system includes a controller circuit including an output pin, the controller circuit arranged to transmit a pulse signal having a pulse width at the output pin; and a plurality of phase circuits, each phase circuit including a respective input pin; a bus connecting the output pin to each respective input pin; and where each of the plurality of the phase circuits is arranged to compare the pulse width of the pulse signal to a predetermined threshold and generate a corresponding respective data signal based on the comparison.

In some embodiments, the pulse width comparator comprises an adjustable delay cell circuit.

### BRIEF DESCRIPTION OF THE DRAWINGS

FIG. 1A illustrates a simplified schematic of a system having multiple integrated circuits connected to a one wire communication protocol, according to some embodiments. FIG. 1B illustrates a one wire communication protocol when an input signal has a pulse width less than a predetermined threshold, according to some embodiments. FIG. 1C illustrates a one wire communication protocol when an input signal has a pulse width greater than a predetermined threshold, according to some embodiments;

FIG. 2 illustrates a circuit schematic for implementation of one wire communication protocol, according to some embodiments; and

FIG. 3A shows a filter used for implementing the pulse width comparator of FIG. 2, according to some embodiments. FIG. 3B shows a delay cell circuit used for implementing the pulse width comparator of FIG. 2, according to some embodiments. FIG. 3C shows a counter circuit used for implementing the pulse width comparator of FIG. 2, according to some embodiments.

### DETAILED DESCRIPTION

Circuits, devices and related techniques disclosed herein relate generally to electronic circuits. More specifically, circuits, devices and related techniques disclosed herein relate to circuits and methods for one wire communication protocol. In some embodiments, circuits and methods for one wire communication protocol can utilize only one external pin of an integrated circuit (IC) to receive input data signal and generate internal data (DATA) and clock (CLK) signals to communicate with internal circuits of the IC. In various embodiments, circuits and methods for one wire communication protocol can generate the internal DATA signal based on a comparison of a pulse width of the input data signal to a predetermined threshold.

In various embodiments, an IC having a communication pin can be connected to a bus and the IC can be arranged to receive a pulse signal having a pulse width via the communication pin. The IC can be arranged to compare the pulse width of the input signal to a predetermined threshold and generate a corresponding data signal based on the comparison. In some embodiments, when the pulse width of the input signal is greater than the predetermined threshold, a corresponding internal data signal can be generated, and when the pulse width of the input signal is less than the predetermined threshold, a corresponding internal inverse data can be generated. In various embodiments, a corresponding internal clock (CLK) signal can also be generated based on the input signal. The CLK signal can be used to read the status of the data. In some embodiments, the internal CLK signal can be generated based on a falling edge of the pulse signal. In various embodiments, the CLK signal can be generated based on a rising edge of the pulse signal.

In some embodiments, a power supply system can include a controller circuit having an output pin, the controller being arranged to transmit a pulse signal having a pulse width at the output pin. The power supply system can further include a phase circuit having an input pin. The power supply system can include a bus that connects the output pin to the input pin. The phase circuit can be arranged to compare the pulse width of the pulse signal to a predetermined threshold and generate a corresponding data signal based on the comparison. Subsequently, corresponding operations are completed according to these data instructions, including but not limited to, reading, writing, enabling disabling and various other functions.

In various embodiments, a power supply system can include a controller circuit including an output pin, the controller being arranged to transmit a pulse signal having a pulse width at the output pin. The power supply system can further include a plurality of phase circuits, each phase circuit having a respective input pin. The power supply system can include a bus that connects the output pin to the input pin. Each of the plurality of the phase circuits can be arranged to compare the pulse width of the pulse signal to a predetermined threshold and generate a corresponding respective data signal based on the comparison. Then corresponding operations are completed according to these data instructions, including but not limited to, reading, writing, enabling disabling and various other functions. Various inventive embodiments are described herein, including methods, processes, systems, devices, and the like.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

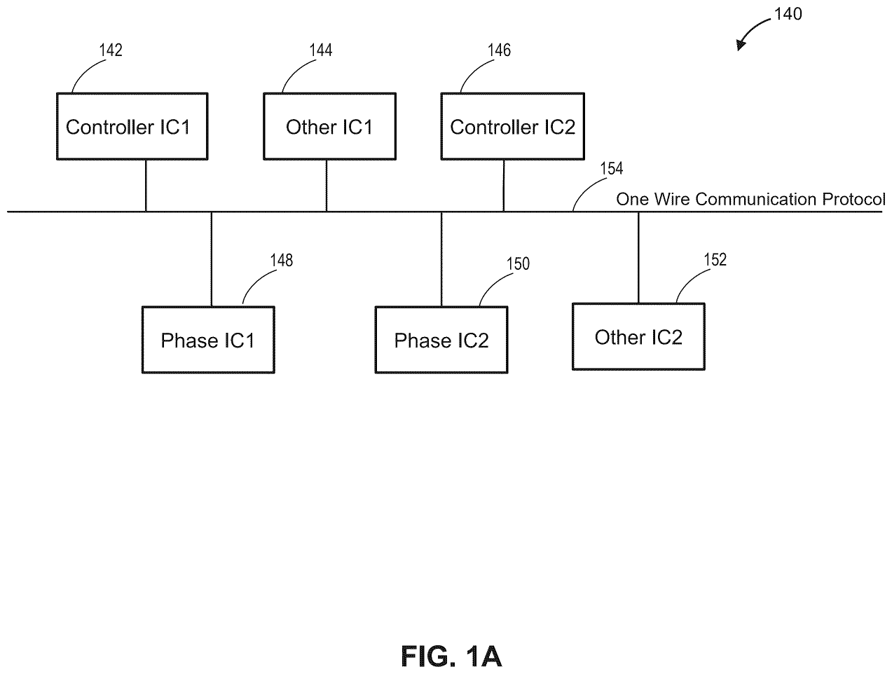

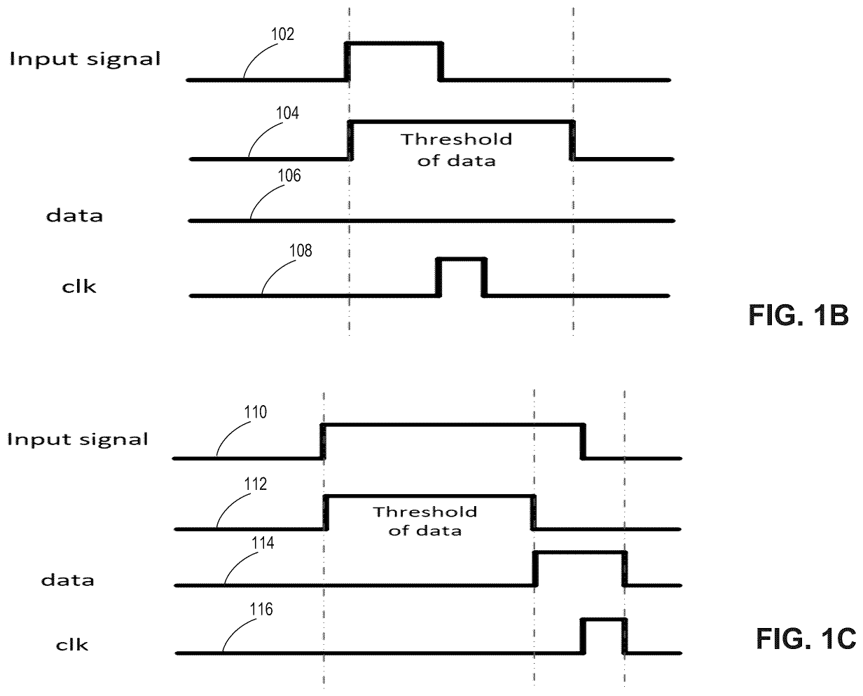

FIG. 1A illustrates a simplified schematic of a system having multiple integrated circuits (IC) connected to a one wire communication protocol, according to some embodiments. System 140 can include one or more controller ICs 142, 146, connected to a one wire communication protocol bus 154. System 140 can also include one or more phase ICs 148, 150, connected to the one wire communication protocol 154. There may also be other ICs 144 and 152, connected to the wire communication protocol bus 154. It shall be understood that other ICs, such as, but not limited to, memory ICs, peripheral ICs, driver ICs and various other ICs can be connected to the one wire communication protocol bus and are within the scope of this disclosure. In some embodiments, the controller ICs can have an output pin connected to the bus. In various embodiments, the phase ICs can have an input pin connected to the bus.

FIG. 1B illustrates a one wire communication protocol when an input signal has a pulse width less than a predetermined threshold, according to some embodiments. FIG. 1C illustrates a one wire communication protocol when an input signal has a pulse width greater than a predetermined threshold, according to some embodiments. As shown in FIG. 1B, an input signal 102 may have a single pulse input signal. The input signal 102 can be compared with a fixed width pulse threshold 104, in order to generate a corresponding data (DATA) signal 106. When the pulse width of the input signal 102 is less than the fixed width pulse threshold 104, the corresponding DATA signal 106 can be set to the inverse of the input data, and when the pulse width of the input signal 102 is greater than the fixed width pulse threshold 104, the corresponding DATA signal 106 can be set according to the input data. As an example, when the input data is 1 and the width of the input data is less than the predetermined pulse width threshold, the internal data to the IC can be set to 0, and when the input data is 1 and the width of the input data is greater than the predetermined pulse width threshold, the internal data to the IC can be set to 1. A clock (CLK) signal 108 can also be generated based on the falling edge of the input signal 102.

FIG. 1B shows an example where the pulse width of the input signal 102 is less than the fixed width pulse threshold 104, therefore internal corresponding data signal is set to 0. Further, the clock signal 108 is generated based on the falling edge of the input signal 102. The clock signal 108 can be used to sample the data signal 106.

FIG. 1C shows an example where an input signal 110 may have a single pulse input signal with a width that is greater than a predetermined pulse width threshold, according to some embodiments. The input signal 110 can be compared with a fixed width pulse threshold 112, in order to generate a data (DATA) signal 114. A clock (CLK) signal 116 can be generated based on the falling edge of the input signal 110. In some embodiments, the value of the fixed width pulse threshold 112 may be equal to the fixed width pulse threshold 104. In FIG. 1C, the pulse width of the input signal 110 is greater than the fixed width pulse threshold 112, therefore data signal is set to 1. Further, the clock signal 116 is generated based on the falling edge of the input signal 102. The clock signal 116 can be used to sample the data signal 114. In some embodiments, the clock signal can be generated using rising edge of the input signal. Other methods of generating the clock signal can be utilized and are within the scope of this disclosure. In various embodiments, a single bit of data and clock signal can be generated by the described methods, and/or multiple bits of data and clock signal can be generated by the described embodiments. Using the above described embodiments, one wire communication protocol can enable one pin in an IC to be used for communication with internal circuits of the IC.

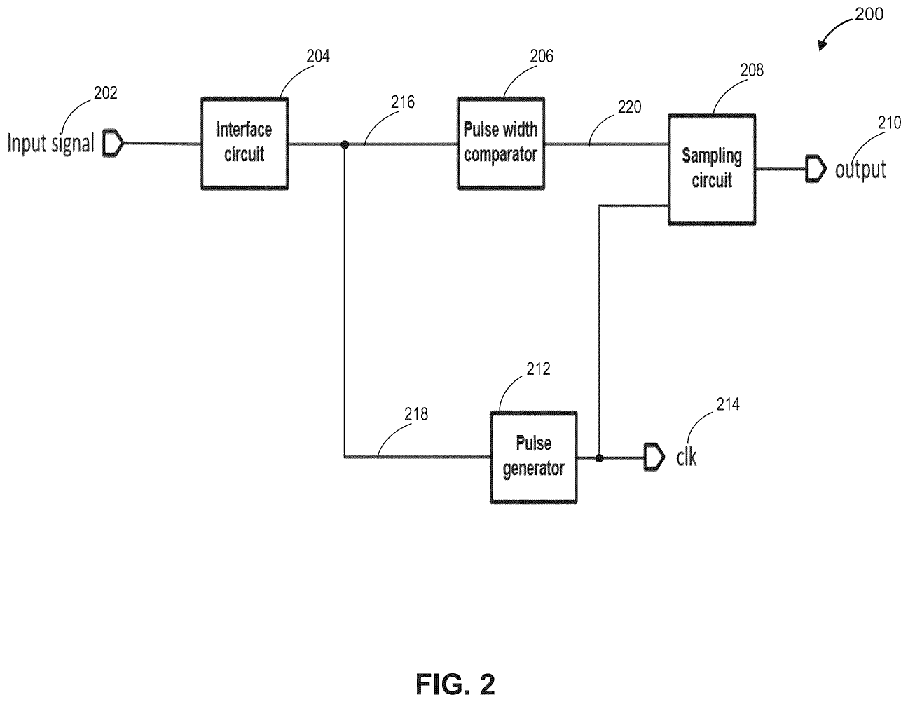

FIG. 2 illustrates a circuit schematic for implementation of one wire communication protocol, according to some embodiments. As shown in FIG. 2, the circuit 200 can include an interface circuit 204, pulse width comparator 206, pulse generator 212, and sampling circuit 208. An input signal 202 can be transmitted through the interface circuit 204. In some embodiments, the interface circuit 204 can be a level shifter to convert external levels into levels compatible with internal circuits of the IC. In various embodiments, the interface circuit 204 can be a filter to filter out noise or spikes in the input signal 202. After passing the interface circuit 204, the date can be is divided into two signals at nodes 216 and 218. The data at node 216 may pass through the pulse width comparator 206. The pulse width comparator 206 can be arranged to compare a width of the data at node 216 to a fixed width pulse threshold 104 in order to generate data (DATA) signal, as described earlier.

Clock signals (CLK) 214 can be generated from data at node 218 by use of a pulse generator 212. In some embodiments, rising edge and/or falling edge of data can be used for generating clock signal 214. Other methods of clock generation can be utilized and are within the scope of this disclosure. Data at node 220 and clock signal 214 may both be transmitted to the sampling circuit 208. The sampling circuit 208 can be arranged to generate output 210.

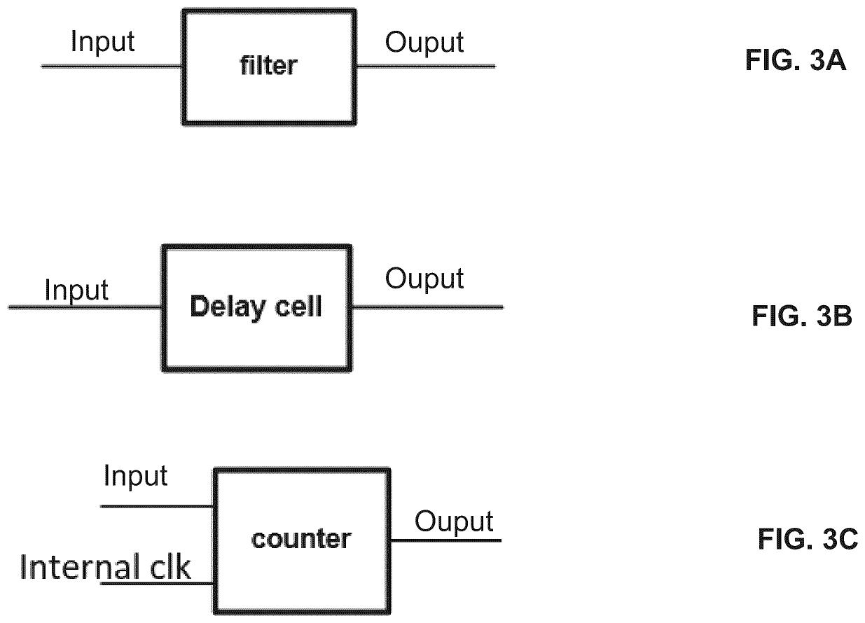

FIGS. 3A-3C show schematics for various implementations for a pulse width comparator of FIG. 2, according to some embodiments. FIG. 3A shows a filter used for pulse width comparison, where an RC filter of the filter can be set. FIG. 3B shows a delay cell circuit used for pulse width comparison where a delay time can be set. FIG. 3C shows a counter used for pulse width comparison, where the comparison is achieved by counting internal clocks.

In some embodiments, combination of the circuits and methods disclosed herein can be utilized to provide a one wire communication protocol. Although circuits and methods are described and illustrated herein with respect to several particular configuration of a one wire communication protocol in power management systems, embodiments of the disclosure are suitable for use as a communication protocol in various electronic systems, such as communication between microcontrollers and various peripherals like sensors, displays, and memory devices.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom or “top” and the like can be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter not be limited to the particular examples disclosed, but that such claimed subject matter may also include all aspects falling within the scope of appended claims, and equivalents thereof.

What is claimed is:

1. A power supply system comprising:
a controller circuit including an output pin, the controller circuit arranged to transmit a pulse signal having a pulse width at the output pin;
a phase circuit including an input pin;
a bus connecting the output pin to the input pin; and
wherein the phase circuit is arranged to compare the pulse width of the pulse signal to a predetermined threshold and generate a corresponding data signal based on the comparison.

2. The power supply system of claim 1, wherein the phase circuit comprises a pulse width comparator arranged to compare the pulse width of the pulse signal to the predetermined threshold.

3. The power supply system of claim 1, wherein the phase circuit comprises a pulse width comparator that is connected to a pulse generator and to a sampling unit.

4. The power supply system of claim 3, wherein the phase circuit is further arranged to generate a clock signal.

5. The power supply system of claim 4, wherein the clock signal is generated based on a falling edge of the pulse signal.

6. The power supply system of claim 4, wherein the clock signal is generated based on a rising edge of the pulse signal.

7. The power supply system of claim 4, wherein the phase circuit is arranged to generate the corresponding data signal when the pulse width of the pulse signal is greater than the predetermined threshold, and generate a corresponding inverse data signal when the pulse width of the pulse signal is less than the predetermined threshold.

8. A communication system comprising:
a bus;
an electronic device having a communication pin connected to the bus, the electronic device arranged to receive a pulse signal having a pulse width via the communication pin; and
wherein the electronic device is arranged to:
compare the pulse width of the pulse signal to a predetermined threshold and generate a corresponding data signal based on the comparison.

9. The communication system of claim 8, wherein the electronic device is a first electronic device and the communication pin is a first communication pin, and wherein the communication system further comprises a second electronic device having a second communication pin connected to the bus, wherein second electronic device is arranged to transmit the pulse signal.

10. The communication system of claim 8, wherein the electronic device is arranged to compare the pulse width using a pulse width comparator.

11. The communication system of claim 8, wherein the electronic device comprises a pulse width comparator, a pulse generator, and a sampling unit.

12. The communication system of claim 8, wherein the electronic device comprises a pulse generator arranged to generate a clock signal based on a falling edge of the pulse signal.

13. A power supply system comprising:
a controller circuit including an output pin, the controller circuit arranged to transmit a pulse signal having a pulse width at the output pin; and
a plurality of phase circuits, each phase circuit including a respective input pin;
a bus connecting the output pin to each respective input pin; and
wherein each of the plurality of the phase circuits is arranged to compare the pulse width of the pulse signal to a predetermined threshold and generate a corresponding respective data signal based on the comparison.

14. The power supply system of claim 13, wherein each of the plurality of phase circuits comprises a pulse width comparator arranged to compare the pulse width of the pulse signal to the predetermined threshold.

15. The power supply system of claim 13, wherein each of the plurality of the phase circuits comprises a pulse width comparator, a pulse generator and a sampling unit.

16. The power supply system of claim 15, wherein each of the plurality of the phase circuits is further arranged to generate a clock signal.

17. The power supply system of claim 16, wherein the clock signal is generated based on a falling edge of the pulse signal.

18. The power supply system of claim 16, wherein the clock signal is generated based on a rising edge of the pulse signal.

19. The power supply system of claim 16, wherein the phase circuit is arranged to generate a corresponding data signal when the pulse width of the pulse signal is greater than the predetermined threshold, and generate a corresponding inverse data signal when the pulse width of the pulse signal is less than the predetermined threshold.

20. The power supply system of claim 15, wherein the pulse width comparator comprises an adjustable delay cell circuit.
